(19) United States
(12) Patent Application Publication
(10) Pub. No.: US 2026/0314431 A1
(43) Pub. Date: Oct. 8, 2026

(54) ASSEMBLY FOR SUB-MICRON ALIGNMENT AND A METHOD FOR SUB-MICRON ALIGNMENT USING THE ASSEMBLY

(71) Applicants: NATIONAL UNIVERSITY OF SINGAPORE, Singapore (SG); POET Technologies Pte. Ltd., Singapore (SG)

(72) Inventors: Chun Fei Siah, Singapore (SG); Yeow Kheng Lim, Singapore (SG); Simon Chun Kiat Goh, Singapore (SG); Yong Meng Lee, Singapore (SG); Suresh Venkatesan, Los Gatos, CA (US)

(21) Appl. No.: 19/482,754

(22) PCT Filed: May 9, 2023
(86) PCT No.: PCT/SG2023/050320

§ 371 Date: Nov. 9, 2025

(51) Int. Cl. H10W 46/00

(52) U.S. Cl. CPC H10W 46/301

(57) ABSTRACT

An assembly for sub-micron alignment is described. In an embodiment, the assembly for sub-micron alignment of a first semiconductor component with a second semiconductor component comprises a protrusion formed on a surface of the first semiconductor component and a cavity formed on a surface of the second semiconductor component adapted to receive the protrusion. Wherein in use, the first semiconductor component is placed in contact with the second semiconductor component via the protrusion to provide a first planar contact, and is subsequently displaced with respect to the second semiconductor component while maintaining the first planar contact to provide a second planar contact between the protrusion and a first cavity wall of the cavity for aligning the first semiconductor component with the second semiconductor component. Embodiments in relation to a method for sub-micron alignment using the assembly are also described.

### TECHNICAL FIELD

The present disclosure relates to an assembly for sub-micron alignment and a method for sub-micron alignment using the assembly, particularly for semiconductor components.

### BACKGROUND

Silicon photonics (SiPh) has been considered the mainstay for the development of optical communication technology for 800G and beyond. As such, SiPh has seen increasing demand for applications in on-chip signalling and data processing. This is in part due to its low latency, CMOS-compatibility, near-zero electromagnetic interference and the potential for large bandwidth.

Most photonic integrated circuits can be broadly classified as homogeneously or heterogeneously integrated. The former includes Ill-V semiconductors formed on a Si substrate either by epitaxial growth or layer transfer. Fabrication efforts for homogenous integration have been hampered by defect dislocations brought forth by lattice mismatch and carrier annihilation. On the other hand, heterogeneously integrated systems typically use singulated known good chips, e.g. laser diodes or modulators, which are assembled onto an interposer platform. Although this can avoid issues, for example, in relation to defect dislocations in homogeneously integrated systems, one main challenge for heterogeneous integration is the stringent requirement for high precision alignment and post-bonding accuracy.

Further, a subsequent bonding and/or reflow process for forming a new electrical and/or mechanical joint between the chip and the interposer following alignment of the chip onto the interposer may command a high thermal budget. Thermal contributions from such a bonding or reflow process has to be considered as these can also influence alignment accuracy.

It is therefore desirable to provide an assembly for sub-micron alignment and a method for sub-micron alignment using the assembly which address the aforementioned problems and/or provides a useful alternative. Further, other desirable features and characteristics will become apparent from the subsequent detailed description and the appended claims, taken in conjunction with the accompanying drawings and this background of the disclosure.

### SUMMARY

Aspects of the present application relate to an assembly for sub-micron alignment and a method for sub-micron alignment using the assembly, particularly for semiconductor components.

In accordance with a first aspect, there is provided an assembly for sub-micron alignment of a first semiconductor component with a second semiconductor component. The assembly comprising: a protrusion formed on a surface of the first semiconductor component; and a cavity formed on a surface of the second semiconductor component adapted to receive the protrusion, wherein in use, the first semiconductor component is placed in contact with the second semiconductor component via the protrusion to provide a first planar contact, and is subsequently displaced with respect to the second semiconductor component while maintaining the first planar contact to provide a second planar contact between the protrusion and a first cavity wall of the cavity for aligning the first semiconductor component with the second semiconductor component.

By having a protrusion formed on a surface of a first semiconductor component and a cavity formed on a surface of the second semiconductor component adapted to receive the protrusion, enhanced alignment accuracy can be achieved by having the first planar contact and the second planar contact between the protrusion and cavity walls of the cavity so as to constrain the degree of freedom of the first semiconductor component with respect to the second semiconductor component, and vice versa, to one. This constraint on the degree of freedom between the first and second semiconductor components thus improves their alignment with each other and reduces alignment error. Further, the protrusion and the cavity pair also provide alignment control along a perpendicular axis (e.g. a Z-axis) of the plane of the first planar contact, for example, by customizing a height or a thickness of the protrusion and/or a recess depth of the cavity. This thus provides a further handle for precise alignment control for aligning the first semiconductor component with the second semiconductor component.

A cross section of the protrusion and a cross-section of the cavity may each has an acute internal angle.

Where a cross-section of the protrusion and the cavity are defined by Cartesian coordinates in an X-Y plane, a minimum difference in lengths between the protrusion and the cavity in the X-direction and a minimum difference in lengths between the protrusion and the cavity in the Y-direction may be equal to a placement accuracy at least of three Sigma of an alignment tool for aligning the first semiconductor component with the second semiconductor component.

A maximum difference in lengths between the protrusion and the cavity in the X-direction and a maximum difference in lengths between the protrusion and the cavity in the Y-direction may be defined by a minimal collision size associated with the protrusion and the cavity, and the minimal collision size may be defined as the maximum differences in the X- and Y-dimensions of the protrusion to the cavity at which edges of the protrusion contact the cavity upon rotation of the protrusion within the cavity.

Wherein a device performance associated with the first semiconductor component or the second semiconductor component is more sensitive in relation to the X-direction than the Y-direction, a difference in lengths in the X-direction between the protrusion and the cavity may be less than a difference in lengths in the Y-direction between the protrusion and the cavity.

Wherein the second semiconductor component may comprise a semiconductor die having an optical diode and the first semiconductor component may comprise an interposer layer having a waveguide formed thereon, a height of the cavity or a height of the protrusion may be adapted to align an optical axis of the optical diode in an X-Y plane of the semiconductor die with the waveguide for coupling light from the optical diode to the waveguide.

Wherein a volume of the protrusion may be adapted to absorb mechanical energy resulted from contact impacts associated with the first and second planar contacts, and to plastically deform without fracturing.

Wherein the cavity may be of a C-shaped or a L-shaped and may be adapted to partially enclose the protrusion when in use.

Wherein the protrusion and the cavity may form a protrusion-cavity pair, the assembly may comprise two or more protrusion-cavity pairs.

Wherein the two or more protrusion-cavity pairs may be arranged at equidistant away from a thermal centre of the first semiconductor component or a thermal centre of the second semiconductor component, and may be on diagonal lines passing through the thermal centre.

The assembly may include four protrusion-cavity pairs, each of the four cavities may be formed at each corner on the surface of the second semiconductor component or at each corner on the surface of the first semiconductor component.

Wherein a distance between each of the two or more protrusion-cavity pairs may be adapted to be as large as possible within processing boundaries of the second semiconductor component.

The first planar contact and the second planar contact may be orthogonal to each other.

The first planar contact may be formed between the protrusion and a second cavity wall of the cavity.

Wherein in use, the first semiconductor component may be displaced with respect to the second semiconductor component while maintaining the first planar contact and the second planar contact to provide a third planar contact between the protrusion and a third cavity wall of the cavity.

In accordance with a second aspect, there is provided a method for sub-micron alignment of a first semiconductor component with a second semiconductor component using an assembly. The assembly comprising a protrusion formed on a surface of the first semiconductor component and a cavity formed on a surface of the second semiconductor component adapted to receive the protrusion. The method comprising: (i) aligning the first semiconductor component with the second semiconductor component to align the protrusion with respect to the cavity; (ii) placing the first semiconductor component in contact with the second semiconductor component to provide a first planar contact via the protrusion; and (iii) displacing the first semiconductor component with respect to the second semiconductor component while maintaining the first planar contact to provide a second planar contact between the protrusion and a first cavity wall of the cavity.

The method may comprise correlating a first fiducial on the surface of the first semiconductor component with a second fiducial on an opposite surface of the first semiconductor component.

The first semiconductor component may comprise an interposer layer and the second semiconductor component may comprise a semiconductor die.

Wherein the protrusion and the cavity may form a protrusion-cavity pair and the assembly may comprise two or more protrusion-cavity pairs, aligning the first semiconductor component with the second semiconductor component may comprise aligning the protrusion with respect to the cavity for each of the two or more protrusion-cavity pairs prior to the step (ii).

Wherein the first planar contact and the second planar contact may be orthogonal to each other.

The method may comprise forming the first planar contact between the protrusion and a second cavity wall of the cavity.

The method may comprise displacing the first semiconductor component with respect to the second semiconductor component while maintaining the first planar contact and the second planar contact between the protrusion and the first cavity wall and the second cavity wall to provide a third planar contact between the protrusion and a third cavity wall of the cavity.

It should be appreciated that features relating to one aspect may be applicable to the other aspects. Embodiments provide a protrusion formed on a surface of a first semiconductor component and a cavity formed on a surface of the second semiconductor component adapted to receive the protrusion, where the protrusion-cavity pair can be used to enhancing alignment accuracy between the first semiconductor component and the second semiconductor component. Particularly, by having the first planar contact and the second planar contact between the protrusion and the cavity walls, the degree of freedom of the first semiconductor component with respect to the second semiconductor component, and vice versa, can be reduced to one. This constraint on the degree of freedom between the first and second semiconductor components thus improves their alignment and reduces an alignment error. Further, the protrusion-cavity pair also provides alignment control along a perpendicular axis (e.g. a Z-axis) of the plane of the first planar contact, for example, by customizing a height or a thickness of the protrusion and/or a recess depth of the cavity. This thus provides a further handle for controlling alignment between the first and second semiconductor components. In some embodiments, the protrusion and the cavity are of complementary geometrical shapes which have a small internal angle (e.g. less than 90°). This provides a tighter control over a rotational alignment between the first semiconductor component and the second semiconductor component and increases an alignment accuracy. In some embodiments, two or more protrusion-cavity pairs can be formed, and they can be placed equidistant away from a thermal centre and on diagonal lines passing through the thermal centre. This helps to ensure an opposite and equal thermal expansion in translational axes due to thermal contribution from any post-alignment thermal processes.

### BRIEF DESCRIPTION OF THE DRAWINGS

Embodiments will now be described, by way of example only, with reference to the following drawings, in which:

FIG. 1 shows a schematic diagram of a perspective view of a protrusion formed on a surface of a semiconductor component in accordance with an embodiment;

FIGS. 2A and 2B show schematic diagrams of a cavity formed on a surface of a semiconductor component in accordance with two embodiments, where FIG. 2A shows a perspective view of a cavity formed within a slot formed on a surface of a semiconductor component and FIG. 2B shows a perspective view of a cavity formed within a cap or a depression formed on a surface of a semiconductor component;

FIG. 3 is a flowchart showing steps of a method for sub-micron alignment of semiconductor components using an assembly comprising the protrusion of FIG. 1 and the cavity of FIG. 2A in accordance with an embodiment;

FIGS. 4A and 4B are schematic diagrams illustrating alignment of a first semiconductor component with a second semiconductor component using an assembly in accordance with an embodiment, where FIG. 4A shows a placement of the first semiconductor component in contact with the second semiconductor component via the protrusion to provide a first planar contact and FIG. 4B shows the displacement of the first semiconductor component with respect to the second semiconductor component while maintaining the first planar contact to provide a second planar contact between the protrusion and a cavity wall of the cavity;

FIGS. 5A, 5B and 5C show schematic diagrams illustrating different planar contacts provided between a protrusion (or a pedestal) and a cavity in accordance with embodiments, where FIG. 5A shows a schematic diagram illustrating a planar contact in the X-Y plane between the protrusion and a first cavity wall of the cavity, FIG. 5B shows a schematic diagram illustrating a planar contact in the X-Z plane between the protrusion and a second cavity wall of the cavity, and FIG. 5C shows a schematic diagram illustrating a planar contact in the Y-Z plane between the protrusion and a third cavity wall of the cavity;

FIGS. 6A, 6B, 6C and 6D show schematic diagrams illustrating effects of a size of an internal angle of a geometrical shape of a protrusion-cavity pair on alignment accuracy in accordance with embodiments, where FIG. 6A shows a schematic diagram illustrating a protrusion-cavity pair having a triangular cross-section, FIG. 6B shows a schematic diagram illustrating a protrusion-cavity pair having a square cross-section, FIG. 6C shows a schematic diagram illustrating clockwise and counter-clockwise rotations of the protrusion within the cavity using the protrusion-cavity pair of FIG. 6A, and FIG. 6D shows a schematic diagram illustrating clockwise and counter-clockwise rotations of the protrusion within the cavity using the protrusion-cavity pair of FIG. 6B;

FIGS. 7A, 7B and 7C show schematic diagrams illustrating effects on a size of an internal angle with variation of a geometrical shape of a protrusion-cavity pair in accordance with embodiments, where FIG. 7A shows schematic diagrams illustrating effects on a size of an internal angle on varying a triangular cross-section of a protrusion-cavity pair, FIG. 7B shows schematic diagrams illustrating effects on the size of an internal angle for a protrusion-cavity pair having a square or a rectangular cross-section and FIG. 7C shows a schematic diagram illustrating effects on the size of an internal angle for a protrusion-cavity pair having a polygonal cross-section;

FIGS. 8A and 8B shows schematic diagrams illustrating a collision size for determining a maximum X- and Y-offsets for protrusion-cavity pairs having different cross sections in accordance with embodiments, where FIG. 8A shows schematic diagrams illustrating a collision size for determining the X- and Y-offsets for a protrusion-cavity pair having a triangular cross-section and FIG. 8B shows schematic diagrams illustrating a collision size for determining the X- and Y-offsets for a protrusion-cavity pair having a square cross-section;

FIG. 9 shows a schematic diagram illustrating four protrusion-cavity pairs and their placements on a die in accordance with an embodiment;

FIG. 10 shows a schematic diagram for illustrating considerations taken for the placement of the four protrusion-cavity pairs of FIG. 9 in accordance with an embodiment;

FIG. 11 shows a schematic diagram illustrating occurrence of an angular error in an event of imperfect alignment in accordance with an embodiment;

FIG. 12 is a flow chart showing steps of a method for sub-micron alignment of a laser diode on an interposer layer and their subsequent bonding process in accordance with an embodiment;

FIGS. 13A, 13B, 13C, 13D, 13E, 13F and 13G show schematic diagrams illustrating the method for sub-micron alignment of the laser diode on the interposer layer and their subsequent bonding process of FIG. 12 in accordance with an embodiment, where FIG. 13A shows a schematic diagram illustrating a correlation between a front surface of a die comprising the laser diode and a fiducial formed on a back surface of the die, FIG. 13B shows a schematic diagram illustrating an interposer layer alignment, FIG. 13C shows a schematic diagram illustrating alignment of the die comprising the laser diode with the interposer layer, FIG. 13D shows a schematic diagram illustrating placement of the die on the interposer layer to form a first planar contact between the die and the interposer layer via a protrusion formed on a surface of the interposer layer, FIG. 13E shows a schematic diagram illustrating an alignment check between the die and the interposer layer, FIG. 13F shows a schematic diagram illustrating displacement of the die with respect to the interposer layer to form a second planar contact between the die and the interposer, and laser-assisted bonding of the die with the interposer layer, and FIG. 13G shows a schematic diagram illustrating a post-bond alignment check between the die and the interposer layer;

FIGS. 14A and 14B show plots of simulated laser-to-waveguide coupling efficiency with respect to deviations from an optical axis of the laser diode in accordance with an embodiment, where FIG. 14A shows a plot of the simulated laser-to-waveguide coupling efficiency with respect to deviations from the optical axis along the x-axis and FIG. 14B shows a plot of the simulated laser-to-waveguide coupling efficiency with respect to deviations from the optical axis along the y-axis;

FIGS. 15A and 15B show images illustrating the laser diode-on-interposer layer alignment in accordance with an embodiment, where FIG. 15A shows an image of a cross-sectional view of a bonded die comprising the laser diode on the interposer layer and FIG. 15B shows an image of a zoomed-in view of a protrusion-cavity pair used in aligning the die with the interposer layer;

FIG. 16 shows a plot of relative axial offsets in placement and bonding along the x-axis using alignment without the incorporation of the protrusion-cavity pair and using the alignment method of 12 in accordance with embodiments;

FIGS. 17A and 17B show plots of relative axial offsets before and after the laser-assisted bonding process of the method in relation to FIG. 12, where FIG. 17A shows a plot of relative axial offsets in the x-direction and the y-direction before and after the laser-assisted bonding process and FIG. 17B shows a plot of relative axial offsets in the θ-direction before and after the laser-assisted bonding process; and

FIGS. 18A and 18B show an image of a bonded laser diode array and their performances in accordance with an embodiment, where FIG. 18A shows an image of the bonded laser diode array and FIG. 18B shows a plot of measured optical performance of the bonded laser diodes.

### DETAILED DESCRIPTION

Exemplary embodiments relate to an assembly for sub-micron alignment and a method for sub-micron alignment using the assembly, particularly for semiconductor components.

It is appreciated that in the present application, the use of the singular includes the plural unless specifically stated otherwise. It should be noted that, as used in the specification and the appended claims, the singular forms “a”, “an” and “the” include plural referents unless the context clearly dictates otherwise. Further, the use of the term “including”, “comprising”, and “having” as well as other forms, such as “include”, “comprise”, “have” are not considered limiting.

As used herein, the term “and/or” includes any and all combinations of one or more of the associated listed items.

In the present embodiments, an assembly comprising (a) a protrusion provided on a first semiconductor component and (b) a cavity provided on a second semiconductor component adapted to receive the protrusion is used for sub-micron alignment of the first and second semiconductor. Particularly, by having the first planar contact and the second planar contact between the protrusion and the respective first and second cavity walls, the degree of freedom between the first semiconductor component and the second semiconductor can be constrained. This constraint the degree of freedom between the first and second semiconductor components, thus improving their alignment and reduces an alignment error. Further, the protrusion-cavity pair also provides alignment control along a perpendicular axis (e.g. a Z-axis) of the plane of the first planar contact, for example, by customizing a height or a thickness of the protrusion and/or a recess depth of the cavity. This thus provides a further handle for precise alignment control between the first and second semiconductor components.

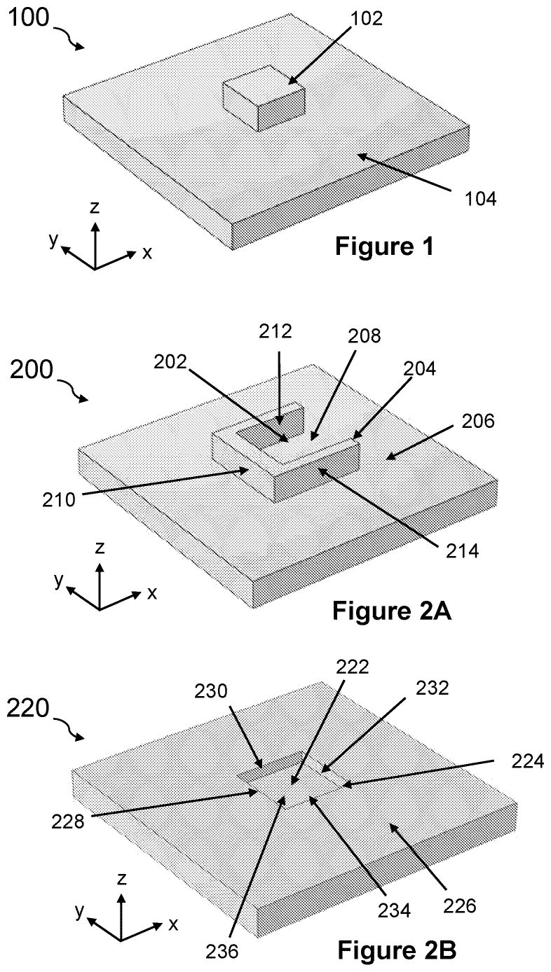

FIGS. 1 to 11 below provide examples of a protrusion and a cavity which can be formed on a first semiconductor component and a second semiconductor component respectively, as well as considerations taken in respect of their geometrical shapes, dimensions and placements for improving an alignment accuracy between the first semiconductor component and the second semiconductor component.

FIG. 1 shows a schematic diagram of a perspective view 100 of a protrusion 102 formed on a surface 104 of a semiconductor component in accordance with an embodiment. The protrusion 102 as shown in FIG. 1 includes a rectangular block or a rectangular pedestal having a square cross-section in the x-y plane. It should be appreciated that other geometrical and/or cross-sectional shapes can be used for the protrusion 102. The protrusion may alternatively be referred to as a pedestal, a plug, a block, and the like.

FIGS. 2A and 2B show schematic diagrams of a cavity formed on a surface of a semiconductor component in accordance with two embodiments. In the present embodiments, the cavity of each of FIGS. 2A and 2B has a complementary shape to the protrusion 102 and can be customised to have suitable dimensions so that the protrusion 102 can be fitted in or fitted within the cavity. In some embodiments, the protrusion 102 may be fitted completely within the cavity, while in other embodiments, the protrusion 102 may be partially fitted within the cavity (e.g. a protrusion can be partially fitted in a cavity formed in a slot). In either case, the protrusion 102 is adapted to make at least two planar contacts with cavity walls of the cavity for use in sub-micron alignment between two semiconductor components. The cavity may be referred to as an envelope, a hole and the like.

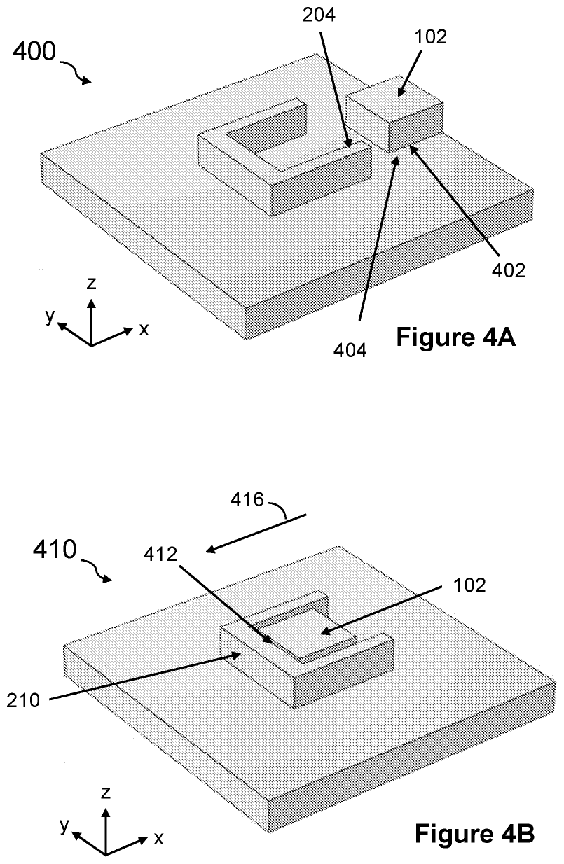

FIG. 2A shows a perspective view 200 of a cavity 202 formed in a slot 204 on a surface of a semiconductor component 206 in accordance with an embodiment. The slot 204, together with a portion of the surface of the semiconductor component 206, forms the cavity walls of the cavity 202. As shown in FIG. 2A, there are therefore four cavity walls formed. A first cavity wall 208 being formed in the x-y plane by the portion of the surface of the semiconductor component 206, a second cavity wall 210 being formed in the y-z plane by a first slot wall of the slot 204, a third cavity wall 212 being formed in the x-z plane by a second wall of the slot 204, and a fourth cavity wall 214 being formed in the x-z plane by a third wall of the slot 204. In the present embodiment, the slot 204 is in the form of a C-shape or a U-shape and is adapted to receive the protrusion 102. In use, the protrusion 102 makes a first planar contact (e.g., the x-y plane) with the first cavity wall 208 of the cavity 202 and is then displaced to make a second planar contact (e.g. the y-z plane) with the second cavity wall 210 of the cavity 202. In some embodiments, the protrusion can make a first planar contact (e.g., in the x-y plane) with the surface of the semiconductor component 206 external to the slot 204, and is then displaced to be within the cavity 202. At this point, the protrusion can be said to make two planar contacts with two cavity walls of the cavity. This is illustrated in relation to FIGS. 4A and 4B and is described below.

FIG. 2B shows a perspective view 220 of a cavity 222 in the form of a cap 224 or a depression formed on a surface of a semiconductor component 226 in accordance with an embodiment. In this case, the four vertical walls 228, 230, 232, 234 of the cap 214 provide four cavity walls of the cavity 222, and there are two cavity walls in the y-z plane (i.e. the walls 228, 232) and two cavity walls in the x-z plane (i.e. the walls 230, 234). The cavity also has a fifth cavity wall in the x-y plane which is provided by a depressed surface 236 of the semiconductor component 226. In an embodiment, when in use, the protrusion 102 makes a first planar contact (e.g., the x-y plane) with the depressed surface 236 (i.e. the fifth cavity wall) of the cavity 202 and is then displaced along the x-axis to make a second planar contact (e.g. the y-z plane) with the vertical wall 228 or the vertical wall 232 of the cavity 202.

By having at least two planar contacts between a protrusion formed on a first semiconductor component and cavity walls of a complementary cavity formed on a second semiconductor component, two elastic-averaging couplings between the protrusion and the cavity can be provided to reduce the degree of freedom between the first and second semiconductor components to one. Particularly, a planar contact formed constrain a motion of the first semiconductor component with respect to the second semiconductor component to be within the plane of the planar contact. Therefore, multiple planar contacts formed under applied loads (also known as elastic averaging coupling) can be used to constrain the degree of freedom of the first semiconductor component with respect to the second semiconductor component, and vice versa, to a desired direction and/or level. For example, one planar contact between a protrusion and a cavity wall constrains the degree of freedoms to three (i.e. two translational and one angular degree of freedom), two planar contacts between the protrusion and two cavity walls constrain the degree of freedom to one (i.e. one rotational degree of freedom) and three planar contacts between the protrusion and two cavity walls constrain the degree of freedom to zero.

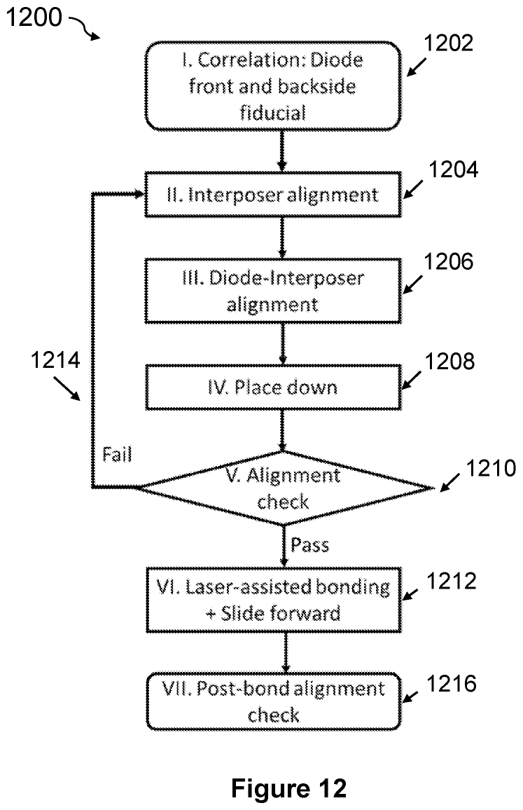

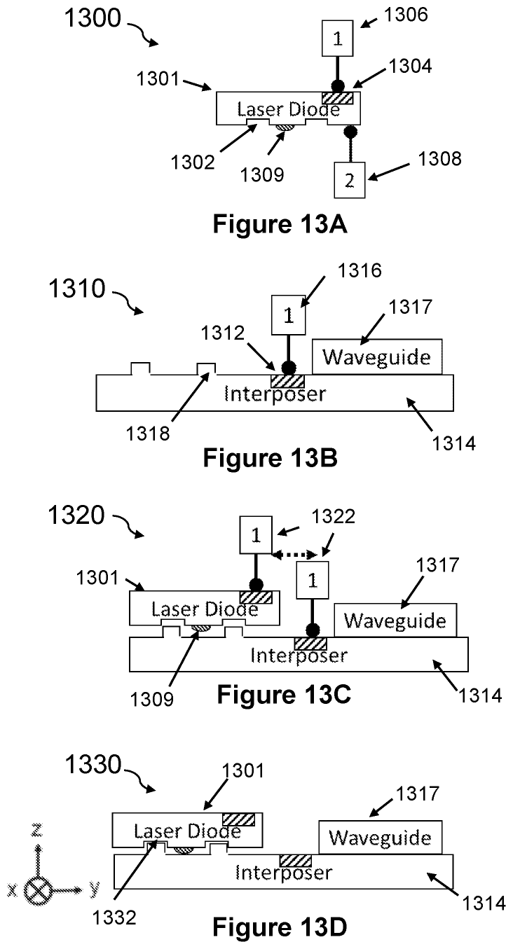

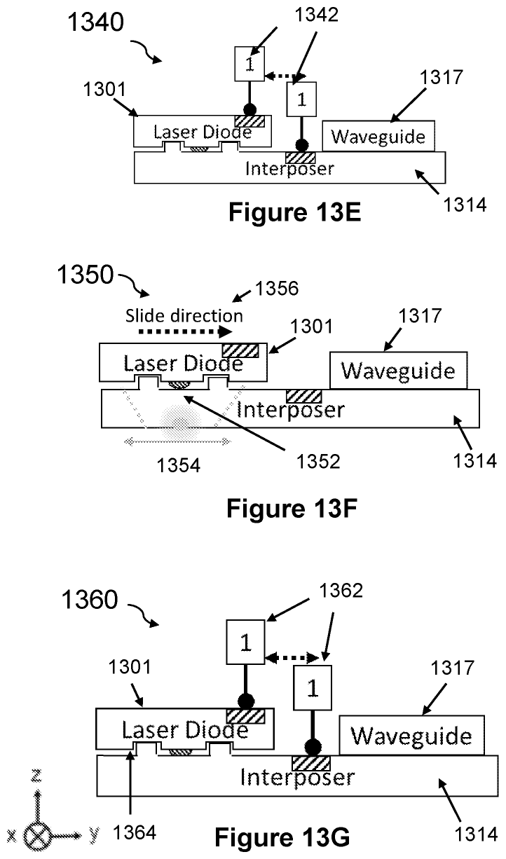

The protrusion and/or the cavity (e.g. formed by a slot or a depression) can be formed using suitable process steps including lithography, etching, deep reactive ion etching and so forth. For example, a protrusion or a slot can be formed on a surface of a semiconductor component by using suitable masking and etching steps to remove any excess parts from the surface of the semiconductor component. Conversely, a depression can be formed on a surface of a semiconductor component by masking the other portions (except for the depression) of the surface and etching away the unmasked area to form the depression. The semiconductor component may include a chip, a die, a substrate, an interposer layer or a redistribution layer etc., and may be formed using one or more semiconductor materials including silicon, germanium or gallium nitride, or using other compatible materials such as tin, copper, aluminium, sapphire and the like. It should also be appreciated that alignment of semiconductor components may also include alignment of electrical or optical semiconductor components form on such semiconductor components, as will be made clear in relation to the example of a laser diode and a waveguide as illustrated in the example of FIGS. 12 to 13G.

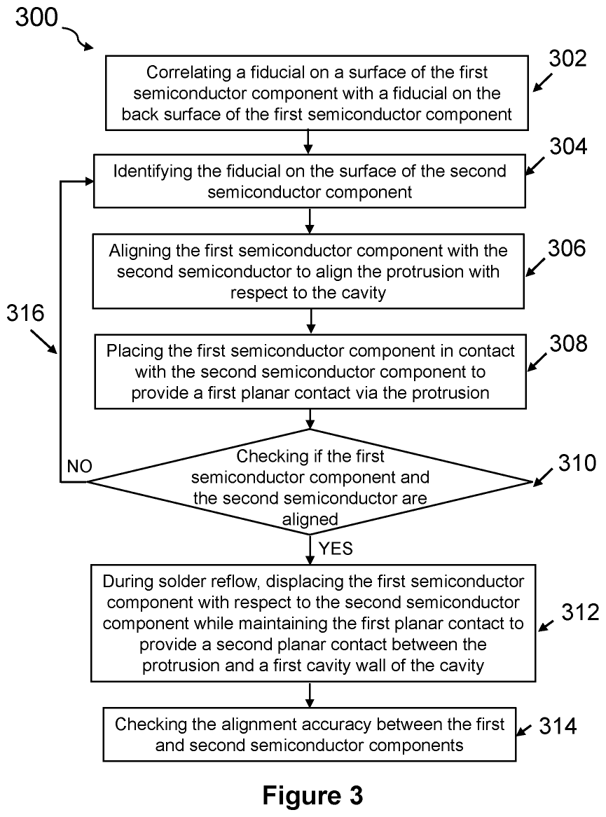

FIG. 3 is a flowchart showing steps of a method 300 for sub-micron alignment of a first semiconductor component with a second semiconductor component using an assembly comprising the protrusion 102 of FIG. 1 and the cavity 202 of FIG. 2A in accordance with an embodiment.

In step 302, a fiducial on a surface of the first semiconductor component is correlated with a fiducial on backside of the first semiconductor component. This is an optional step but is helpful particularly for an embodiment which involves flip-chip integration. For flip-chip integration, a camera in a bonding/destination station typically only provides a top view of the chip. As the chip was ‘flipped’ (i.e. with a front side of the chip being faced down), there is no way to look at the front side of the chip directly during placement. To overcome this difficulty, a correlation between the fiducial on the surface (i.e. the front side) and the fiducial on the backside of the chip is performed at a middle station with top and bottom cameras, before proceeding to the bonding station.

In step 304, the fiducial on the surface of the first semiconductor component is identified, for example, by using an alignment camera of an alignment system or a bonding system.

In step 306, the first semiconductor component is aligned with the second semiconductor component to align the protrusion 102 with respect to the cavity 202. In the present embodiment, the first semiconductor component is aligned atop of the second semiconductor component during the assembly process. In the present embodiment, aligning the first semiconductor component with the second semiconductor component comprises aligning the fiducial of the first semiconductor component with the fiducial on the surface of the second semiconductor component. A good alignment between the first semiconductor component and the second semiconductor component ensures a good alignment between the protrusion and the cavity. In another embodiment, the step 306 includes aligning the first semiconductor component with the second semiconductor component by spatially overlapping the protrusion with the cavity (e.g. in the embodiment where the cavity is formed by a cap or a depression as shown in relation to FIG. 2B).

In step 308, the first semiconductor component is placed in contact with the second semiconductor component to provide a first planar contact between the first semiconductor component and the second semiconductor component via the protrusion. By forming the first planar contact, the degree of freedom of the first semiconductor component with respect to the second semiconductor component is constrained to three. In the present case where the first planar contact is in the x-y plane, then the degree of freedom includes the x-axis and the y-axis (i.e. two translational degrees of freedom) and the θ-axis (i.e. one angular degree of freedom). Further, a height of the protrusion and/or a depth of the cavity can be customized to provide control in the vertical or the z-direction (i.e. along a perpendicular axis to the first planar contact).

In step 310, the first semiconductor component and the second semiconductor component are checked to see if they are aligned within an acceptable offset. If the alignment between the first semiconductor component and the second semiconductor component are acceptable, the assembly process will proceed to step 312.

In the step 312, the first semiconductor component is displaced with respect to the second semiconductor component during solder reflow, while maintaining the first planar contact, to provide a second planar contact between the protrusion and a first cavity wall of the cavity. In the present embodiment, this step 312 includes a sliding motion along the x-axis to bring the protrusion into contact with the first cavity wall of the cavity (e.g. into contact with the cavity wall on the y-z plane). With the two planar contacts between the protrusion and the cavity walls, the first semiconductor component is ideally restrained to one degree of freedom (i.e. an angular degree of freedom along a θ-axis, where θ is in the x-y plane).

In a step 314, the alignment accuracy between the first and second semiconductor components are checked. This step is performed to ensure proper alignment between the first and second semiconductor components even after solder reflow.

If the first semiconductor component and the second semiconductor component are found to be not within acceptable range in the step 312, then the alignment process reverts in step 316 back to the step 304 where the steps 304 to 310 as afore-described will be performed again.

FIGS. 4A and 4B are schematic diagrams illustrating alignment of the first semiconductor component with the second semiconductor component using the assembly comprising the protrusion 102 and the cavity 202 formed using the slot 204 in accordance with an embodiment. It should be appreciated that the protrusion 102 can be formed on a back surface of the first semiconductor component. The first semiconductor component, however, is not shown in FIGS. 4A and 4B for succinctness and clarity.

FIG. 4A shows a schematic diagram 400 illustrating a placement of the first semiconductor component in contact with the second semiconductor component to provide a first planar contact 402 via the protrusion 102. In the present embodiment as shown in FIG. 4A, the first planar contact 402 is made between the protrusion 102 and a surface portion 404 of a surface of the second semiconductor component in the x-y plane. The first planar contact 402 in the present embodiment is external to the slot 204 as shown in FIG. 4A. It should be appreciated that in other embodiments, the protrusion 102 can be placed within or partially within the cavity 202 to form the first planar contact 402. In those cases, the first planar contact can be said to be formed between the protrusion 102 and a cavity wall 208 of the cavity 202, where the cavity wall is formed in the x-y plane by a portion of a surface of the second semiconductor component. In any case, the first planar contact, whether made outside of the slot 204, or partially within or within the slot 204, is sufficient for the performance of the present invention as long as a displacement of the first semiconductor component with respect to the second semiconductor component, while maintaining the first planar contact, provides a second planar contact between the protrusion 102 and a cavity wall of the cavity 202.

FIG. 4B shows a schematic diagram 410 illustrating a displacement of the first semiconductor component with respect to the second semiconductor component to provide a second planar contact between the protrusion and a cavity wall. The first semiconductor component is displaced with respect to the second semiconductor component, while maintaining the first planar contact 402 via the protrusion 102, to provide a second planar contact 412 between the protrusion 102 and a cavity wall 210 of the cavity 202. In the present embodiment, this involves a sliding motion 416 along the x-axis to bring the protrusion 102 into contact with the cavity wall 210 of the cavity (e.g. into contact with the cavity wall on the y-z plane. In the present embodiment, the protrusion 102 is adapted to fit within the cavity, and by displacing the protrusion 102 while maintaining the first planar contact 402 via the protrusion 102, two planar contacts between the protrusion 102 and cavity walls 208, 210 are formed at the end of the displacement. The two planar contacts formed between the protrusion 102 and cavity walls 208, 210 ideally restrained the first semiconductor component to one degree of freedom (i.e. an angular degree of freedom along a θ-axis) with respect to the second semiconductor component.

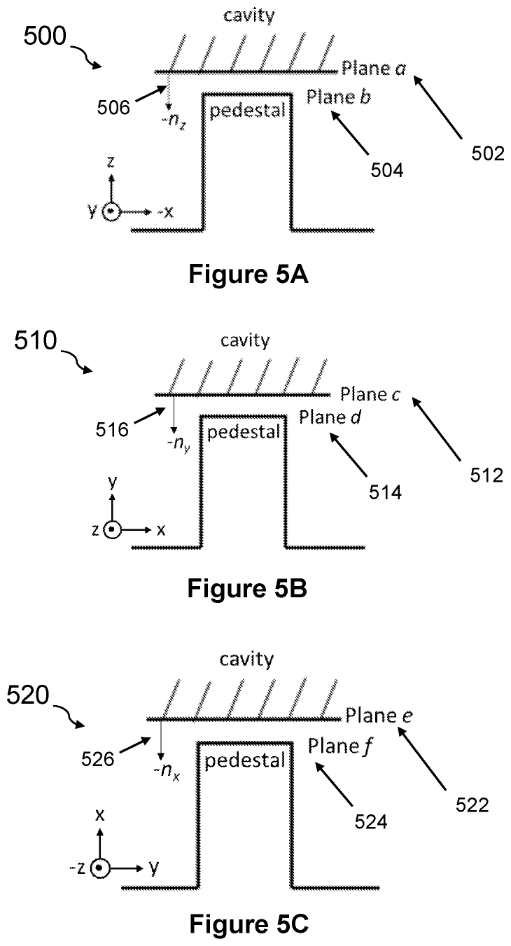

FIGS. 5A, 5B and 5C show schematic diagrams illustrating different planar contacts provided between a protrusion (or a pedestal) and a cavity wall of a cavity in accordance with embodiments.

FIG. 5A shows a schematic diagram 500 illustrating a planar contact in the x-y plane between Plane a 502 of a cavity wall of the cavity and Plane b 504 of the protrusion. The planar contact in the x-y plane can be formed by translating or displacing the cavity along the negative z-direction 506 with respect to the protrusion.

FIG. 5B shows a schematic diagram 510 illustrating a planar contact in the x-z plane between Plane c 512 of a cavity wall of the cavity and Plane d 514 of the protrusion. The planar contact in the x-z plane can be formed by translating or displacing the cavity along a negative y-direction 516 with respect to the protrusion.

FIG. 5C shows a schematic diagram 520 illustrating a planar contact in the y-z plane between Plane e 522 of a cavity wall of the cavity and Plane f 524 of the protrusion. The planar contact in the y-z plane can be formed by translating or displacing the cavity along a negative x-direction 526 with respect to the protrusion.

Multi-axial elastic averaging coupling between the protrusion and the cavity walls can therefore be formed along one or more of planes as described above.

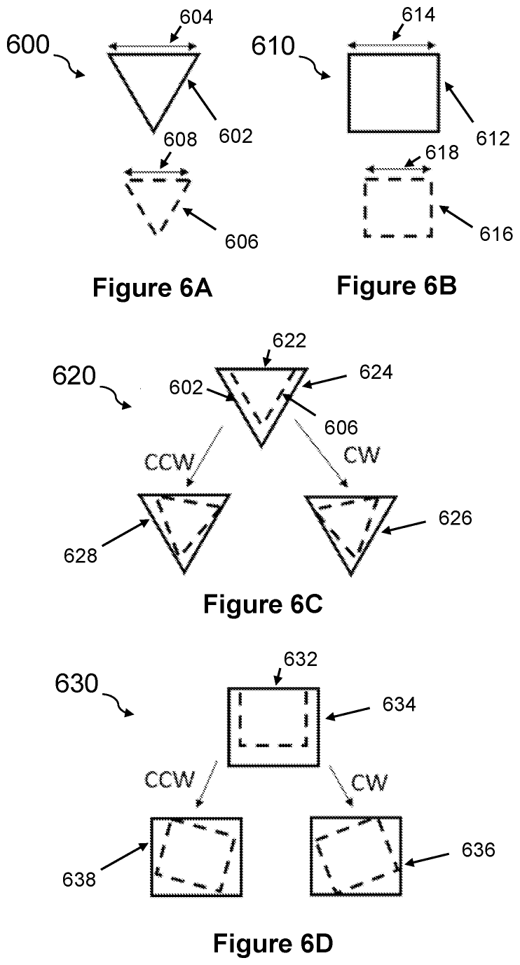

FIGS. 6A, 6B, 6C and 6D show schematic diagrams illustrating effects of a size of an internal angle of a geometrical shape of a protrusion and a cavity on alignment accuracy in accordance with embodiments. Although this appears to be applicable to embodiments where the cavity is in the form of a depression, for example as shown in FIG. 2B, the principles of using small internal angles for the geometric shape of the protrusion and the cavity to improve alignment accuracy can also be applied in embodiments where the cavity is in the form of a slot, for example as shown in FIG. 2A.

FIG. 6A shows a schematic diagram 600 illustrating a protrusion-cavity pair having a triangular cross-section. In this embodiment, the cavity 602 has a cross-section in the shape of an equilateral triangle, where each side 604 of the cavity 602 has a same length. Similarly, the protrusion 606 has a cross-section in the shape of an equilateral triangle, where each side 608 of the protrusion 606 has a same length. As shown in FIG. 6A, the cross-sectional area of the cavity 602 is larger than the cross-sectional area of the protrusion 606 so that the protrusion 606 can be fitted within the cavity 602. The internal angles of the equilateral triangle cross-section are each at 60°.

FIG. 6B shows a schematic diagram 610 illustrating a protrusion-cavity pair having a square cross-section. In this embodiment, the cavity 612 has a cross-section in the shape of a square, where each side 614 of the cavity 612 has a same length. Similarly, the protrusion 616 has a cross-section in the shape of a square, where each side 618 of the protrusion 616 has a same length. As shown in FIG. 6B, the cross-sectional area of the cavity 612 is larger than the cross-sectional area of the protrusion 616 so that the protrusion 616 can be fitted within the cavity 612. The internal angles of the equilateral square cross-section are each at 90°.

FIG. 6C shows a schematic diagram 620 illustrating clockwise rotation and counter-clockwise rotation of the protrusion 606 within the cavity 602 using the protrusion-cavity pair of FIG. 6A. In line with the method 300, the protrusion 606 is displaced while maintaining a first planar contact to provide a second planar contact between the protrusion 606 and a cavity wall 622 of the cavity 602 as shown in the configuration 624. The effect of a magnitude of an internal angle of the protrusion 606 and the cavity 602 can then be considered by rotating the protrusion 606 with respect to the cavity 602 clockwise and counter-clockwise as shown in the configurations 626 and 628, respectively.

FIG. 6D shows a schematic diagram 630 illustrating clockwise rotation and counter-clockwise rotation of the protrusion 614 within the cavity 612 using the protrusion-cavity pair of FIG. 6B. Similar to that shown in FIG. 6C, the protrusion 614 is displaced while maintaining a first planar contact to provide a second planar contact between the protrusion 614 and a cavity wall 632 of the cavity 612 as shown in the configuration 634. The effect of a magnitude of an internal angle of the protrusion 616 and the cavity 612 can then be considered by rotating the protrusion 616 with respect to the cavity 612 clockwise and counter-clockwise as shown in the configurations 636 and 638, respectively.

From the discussions in relation to FIGS. 6A to 6D, it is evidenced that a triangular cross-section of the protrusion-cavity pair, which has a smaller internal angle of 60° as compared to the internal angle of a square cross-section which is 90°, enables an earlier collision between the pair of protrusion 606 and cavity 602 when there is unintended lateral movement or rotation, as compared to the pair of protrusion 616 and cavity 612. This makes the triangular protrusion-cavity pair more effective in reducing alignment error as compared to the square protrusion-cavity pair. This provides tighter control in an alignment spread (e.g. at 3 sigma accuracy), reduces cosine error (also known as angular error) effectively, and can be used to achieve better post-bond alignment accuracy.

Although an equilateral triangle cross-section and a square cross-section, which have equal sides and equal internal angles, are used in these examples, it should be appreciated that other geometrical cross-sections can be used. For example, a trapezium-shaped protrusion-cavity pair having different internal angles can also be used. The restraint on the rotation of the trapezoid-shaped protrusion within the cavity can be provided by the smaller internal angles of the trapezoidal shape and can be designed to provide effective alignment control. Further, it can be envisaged that protrusion-cavity pair having other polygonal cross-sections can be used. This may include quadrilateral shapes such as a square, a rectangle, a parallelogram, a trapezium, a rhombus, or a kite shape. Where acute angles are formed together with obtuse angles in a cross-section, for example in a polygonal cross-section, or a quadrilateral cross-section such as a parallelogram or a trapezium cross-section, a more effective alignment can be made if the planar surface (or a portion of the planar surface) at which the protrusion and cavity wall make planar contact forms a side of at least one of the acute angles of the quadrilateral cross-section.

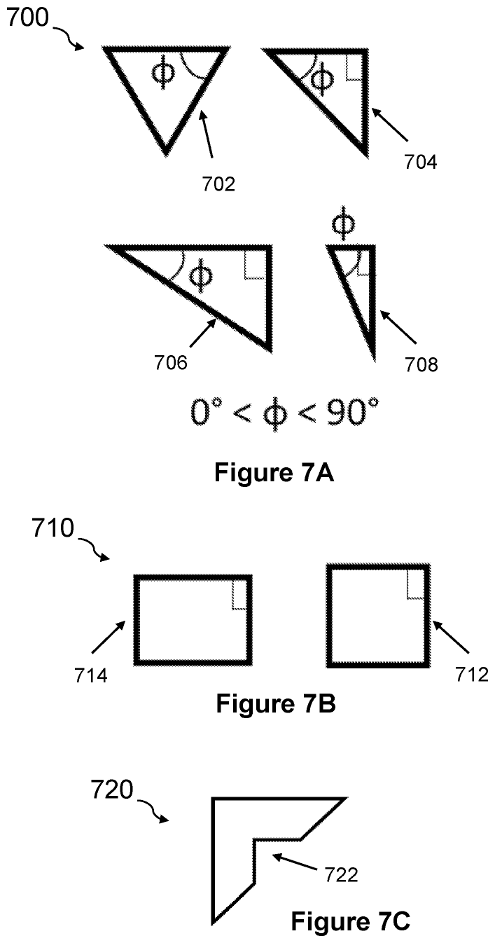

FIGS. 7A, 7B and 7C show schematic diagrams illustrating effects on a size of an internal angle with variation of a geometrical shape of a protrusion and a cavity in accordance with embodiments.

FIG. 7A show schematic diagrams 700 illustrating effects on the size of an internal angle on variation of a protrusion-cavity pair having a triangular cross-section. Variations on the triangular cross-sections are shown in relation to triangles 702, 704, 706, 708. As illustrated by these triangles 702, 704, 706, 708, an internal angle φ is always between 0° and 90°.

FIG. 7B show schematic diagrams 710 illustrating effects on the size of an internal angle on variation of a protrusion-cavity pair having a square or a rectangular cross-section. As shown in FIG. 7B, each of the square cross-section 712 or the rectangular cross-section 714 has an internal angle of 90°, which is larger than the internal angle φ of a triangular cross-section.

FIGS. 7A and 7B therefore further demonstrate that a triangular cross-section for a protrusion-cavity pair provides a smaller internal angle as compared to a square cross-section or a rectangular cross-section for a protrusion-cavity pair. The triangular cross-section for the protrusion-cavity pair may therefore be preferred over that of a square cross-section or a rectangular cross-section.

In addition, FIG. 7C shows a schematic diagram 720 illustrating effects on the size of an internal angle for a protrusion-cavity pair having a polygonal cross-section. The polygonal shape as shown in FIG. 7C has a generally triangular cross-section, except for a notch/cavity 722 formed on a hypotenuse. The notch/cavity 722 provides additional planar contacts for the protrusion-cavity pair and may therefore further constrain the degree of freedom of the first semiconductor component with respect to the second semiconductor component.

Besides an internal angle of a geometrical shape for a cross-section of a protrusion-cavity pair, differences in dimensions between the protrusion and the cavity can also affect an alignment accuracy. In the present disclosure, for succinctness, the differences in dimensions between the protrusion and the cavity are termed as “offsets”. Further, in the present embodiments, the cross-sections of the protrusion and the cavity are considered in the X-Y plane, and therefore, the offsets are also correspondingly termed as X-offsets for offsets along the x-axis, and Y-offsets for offsets in along the y-axis. It should, however, be appreciated that the cross-sections of the protrusion and the cavity can be in other planes.

Because the protrusion is placed within or partially within the cavity when the first semiconductor component is placed in contact with the second semiconductor component, offsets are introduced to enable an easier placement or alignment of the protrusion with respect to the cavity. The minimum X-offsets and Y-offsets are determined by a machine placement accuracy @ 3 sigma. For example, the AMICRA NANO bonder has a placement accuracy of 0.3 μm @ 3 sigma. Therefore, a protrusion-cavity pair for use with the AMICRA NANO bonder has a minimum X-offsets and Y-offsets set as 0.3 μm. The minimal offsets provide a tight fitting of the protrusion-cavity pair and high alignment accuracy. However, small offsets place higher burden on a placement accuracy and may increase a probability for placement errors due to misplacement of the protrusion with respect to the cavity.

On the other hand, the maximum X-offsets and Y-offsets are determined by the smallest collision size in relation to a geometrical shape of the protrusion-cavity pair. Using maximum X- and Y-offsets provide a loose fitting of the protrusion-cavity pair but enables an easier alignment process at the cost of alignment accuracy.

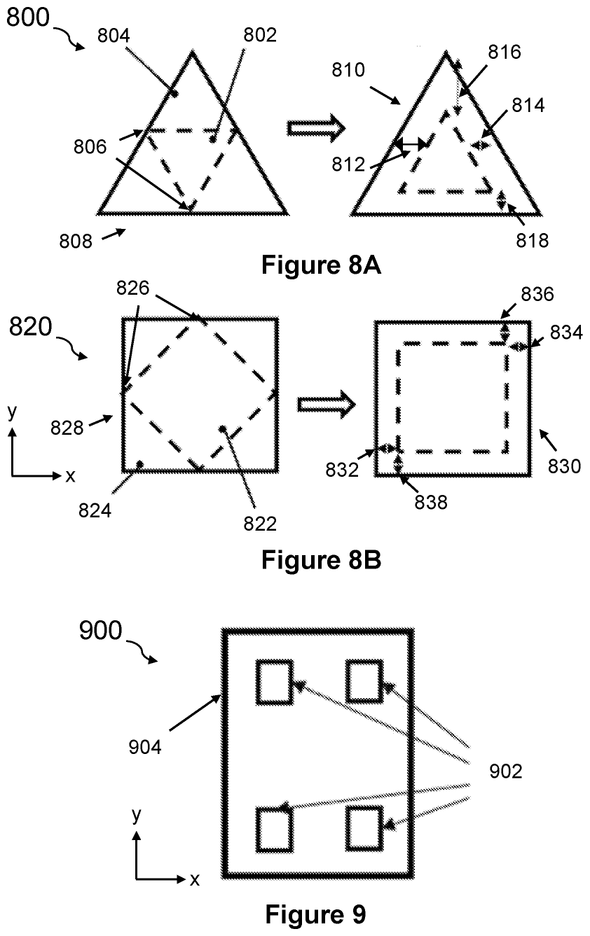

FIGS. 8A and 8B shows schematic diagrams 800, 820 illustrating a collision size for determining maximum X- and Y-offsets for protrusion-cavity pairs having different cross sections in accordance with embodiments.

FIG. 8A shows schematic diagrams 800 illustrating a collision size for determining the X-offsets and Y-offsets for a protrusion-cavity pair having a triangular cross-section. As shown in FIG. 8A is a protrusion 802 having a smallest collision size or cross-sectional area being fitted within a complementary cavity 804. The smallest collision area relates to the smallest cross-sectional area of the protrusion 802 which still enables collision or contact between the protrusion 802 and its corresponding cavity 804 upon rotation. For an equilateral triangular cross-section, this involves having the corners 806 of the equilateral triangle being in contact at a middle of each edge of the cavity 804 as shown in the left panel 808 of FIG. 8A.

The right panel 810 of FIG. 8A shows the protrusion 802 being rotated (e.g. 180° clockwise or counter-clockwise) so that the protrusion 802 is in a same orientation as the complementary cavity 804. This right panel 810 shows the maximum X-offsets 812, 814 and the maximum Y-offsets 816, 818 associated with this equilateral triangular cross-sectional protrusion-cavity pair.

FIG. 8B shows schematic diagrams 820 illustrating a collision size for determining the X- and Y-offsets for a protrusion-cavity pair having a square cross-section.

As shown in FIG. 8B is a protrusion 822 having the smallest collision size or cross-sectional area being fitted within a complementary cavity 824. For the square cross-section, this involves having the corners 826 of the square being in contact at a middle of each edge of the cavity 824 as shown in the left panel 828 of FIG. 8B. The right panel 830 of FIG. 8B again shows the protrusion 822 being rotated (e.g. 90° clockwise or counter-clockwise) so that the protrusion 822 is in a same orientation as the complementary cavity 824. This right panel 830 shows the maximum X-offsets 832, 834 and the maximum Y-offsets 836, 838 associated with this square cross-sectional protrusion-cavity pair.

FIG. 9 shows a schematic diagram 900 illustrating four protrusion-cavity pairs 902 and their placements on a semiconductor component in accordance with an embodiment. As shown in FIG. 9, the four protrusion-cavity pairs 902 are placed at each corner of a semiconductor component 904 (e.g. a die).

Theoretically, one protrusion-cavity pair with very tight fitting (i.e. minimal X-offsets and Y-offsets) may be sufficient to provide adequate alignment between the first and second semiconductor components. Practically, a minimal of two protrusion-cavity pairs can be used to minimise particularly a rotational error due to offsets between the protrusion and the cavity. If two protrusion-cavity pairs are used, they should preferably be placed in a line of symmetry with respect to the semiconductor components and/or be as far away from each other as practicable. There is no maximum number of protrusion-cavity pairs that can be used as long as the protrusion-cavity pairs do not affect the functionalities of the semiconductor components involved in the alignment.

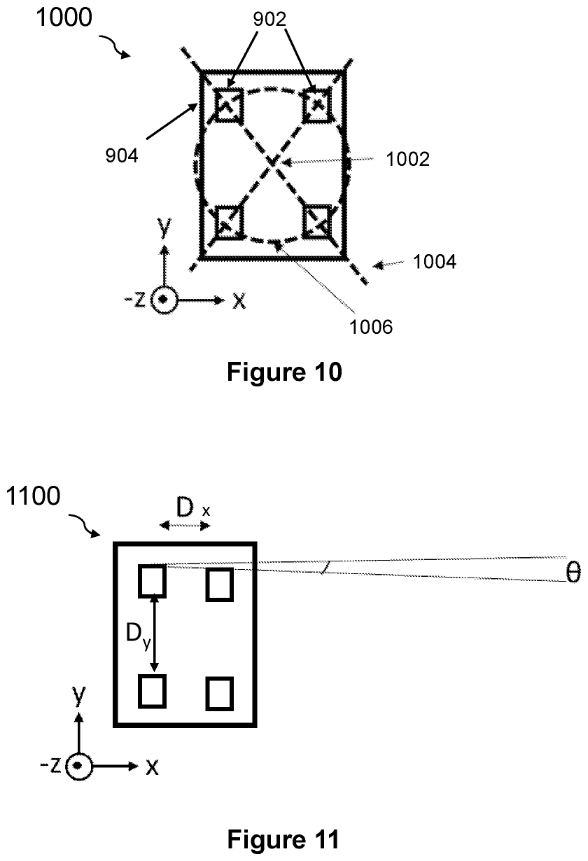

In the present embodiment as shown in FIG. 9, four protrusion-cavity pairs 902 are placed at each corner of the semiconductor component 904 to form two lines/planes of symmetry with respect to the x-y plane of the semiconductor component. This is shown more clearly in relation to FIG. 10.

FIG. 10 shows a schematic diagram 1000 for illustrating considerations taken for the placement of the four protrusion-cavity pairs 902 of FIG. 9 in accordance with an embodiment.

As shown in FIG. 10, the protrusion-cavity pairs 902 are placed equidistant away from a centre 1002 and on diagonal lines 1004 passing though the centre 1002 of the semiconductor component 904. A circle 1006 for illustrating that the protrusion-cavity pairs 902 are at equidistant away from the centre 1002 is also shown in FIG. 10.

Placing the protrusion-cavity pairs 902 equidistant away from a centre 1002 and on diagonal lines 1004 passing though the centre 1002 of the semiconductor component 904 is useful for at least two reasons. First, if the centre 1002 is also a thermal centre (e.g. in relation to a subsequent bonding process), then having the protrusion-cavity pairs arranged in this way allow for opposite and equal thermal expansion from the thermal centre due to thermal contributions. Second, when semiconductor components associated with these protrusion-cavity pairs 902 are placed in contact with each other, loads are applied with the protrusion-cavity pairs being the contact points. Having the protrusion-cavity pairs 902 being placed at lines/planes of symmetry can redirect loading stresses, such that when the protrusion-cavity pairs 902 undergo stresses/strains, the stresses/strains will be redistributed over the protrusion-cavity pairs 902. This is another reason for having more than one protrusion-cavity pair for alignment. Further, even if the protrusion-cavity pairs 902 undergo mechanical deformation, objects on the semiconductor component 904 along the lines/planes 1004 of symmetry and aligned relative to each other will remain in alignment even after mechanical deformation of the protrusion-cavity pairs 902.

A volume of a protrusion can be considered in relation to mechanical deformation. The below Equation (1) provides guidance for determining a minimum volume for a protrusion where mechanical energy (e.g. a load) can be absorbed by the protrusion so that the protrusion can plastically deform without fracturing.

$$\frac{energy}{volume} = {\int }_{0}^{{ε}_{f}} σ d ε \qquad ( 1 )$$

where ε is strain, ε_{f} is strain upon failure, and σ is stress.

There is no limit for a maximum volume of the protrusion provided that the protrusion is not too large so that it disrupts the functionalities of the associated semiconductor components.

FIG. 11 shows a schematic diagram 1100 illustrating an occurrence of angular errors in an event of imperfect alignment in accordance with an embodiment.

To minimize an angular error resulting from imperfect alignment due to, for example, machine capabilities and manufacturing tolerances, distances between protrusion-cavity pairs should be as large as possible while remaining in manufacturable boundaries.

In an imperfect alignment, for example as shown in FIG. 11, an angular error θ with respect to the x-axis can be introduced. Equation (2) below provides the relationship between the angular error θ, the X-offset and Y-offset in relation to a protrusion-cavity pair, as well as the distance Dₓ between two protrusion-cavity pairs along the x-axis.

$$tan {θ}_{max} = \frac{{Y}_{offset}}{2 {X}_{offset} + {D}_{x}} \qquad ( 2 )$$

where X_{offset} and Y_{offset} are the offsets introduced along the x-direction and the y-direction respectively, and Dₓ is the distance between two protrusion pairs along the x-axis.

Assuming X_{offset}/Dₓ< 1/100, and Y_{offset}/Dₓ< 1/10, then using small angle approximation, Equation (2) becomes:

$${θ}_{max} \approx \frac{{Y}_{offset}}{{D}_{x}} \qquad ( 3 )$$

The same principle can be applied in relation to the y-axis for angular error Ω as shown in Equation (4) below:

$${Ω}_{max} \approx \frac{{X}_{offset}}{{D}_{y}} \qquad ( 4 )$$

where Ω is the angular error with respect to the y-axis and D_{y} is the distance between two protrusion-cavity pairs along the y-axis as shown in FIG. 11.

Therefore, to minimize angular errors for aligning the semiconductor components, Dₓ and D_{y} should be arranged to be as large as possible but within the manufacturable boundaries of the semiconductor components.

FIGS. 1 to 11 above provide discussions in relation to the geometrical shapes, dimensions and placement of protrusion-cavity pairs for aligning two semiconductor components. An example of the above assembly and method of alignment is described in relation to FIGS. 12 to 20B below. Particularly, the present example includes a flip-chip laser diode aligned on an interposer layer using the method 300 and was bonded on the interposer layer using laser-assisted bonding (LAB) to effectively minimise the heat-affected zone (HAZ). Consistent sub-micron alignment accuracy is particularly advantageous for the integration of laser diodes onto a photonic circuit because light produced by the laser diode is subsequently launched into a waveguide. Misalignment between the laser diode and the waveguide will lead to coupling loss, stray light, and unwanted localized heating due to the need to increase the input power of the laser diode to compensate coupling loss.

FIG. 12 is a flow chart showing steps of a method 1200 for sub-micron alignment of a laser diode on an interposer layer and their subsequent bonding process in accordance with the present embodiment. The steps of the method 1200 are similar to that as described in the method 300 so the method 1200 will only be briefly described below for succinctness. Particularly, steps 1202, 1204 and 1206 relates to initial alignment steps performed by an alignment system (e.g. a bonder), steps 1208, 1210 and 1212 relates to the alignment steps performed using protrusion-cavity pairs described in the present disclosure, and step 1216 relates to a post-bond alignment check.

In the step 1202, a front surface of a die comprising the laser diode is correlated with a fiducial on a back surface of the die. This is illustrated in a schematic diagram 1300 of FIG. 13A where it is shown the die 1301 having a front surface comprising a cavity 1302 and a fiducial 1304 formed on a back surface of the die 1301. Alignment cameras 1306, 1308 of an alignment system (e.g. a bonding machine) can be used to correlate the front surface of the die (e.g. by using a specific feature on the front surface or another fiducial) with the fiducial 1304 of the die. In the present embodiment, the front surface of the die 1301 also includes a solder ball 1309 which is used in a subsequent bonding step.

In the step 1204, alignment of the interposer layer is performed. This is illustrated in a schematic diagram 1310 of FIG. 13B where it is shown a fiducial 1312 formed on a surface of the interposer layer 1314 being identified using an alignment camera 1316 of the alignment system. As shown in FIG. 13B, the interposer layer 1314 in the present embodiment includes a waveguide 1317 and a protrusion 1318 formed on the surface of the interposer layer 1314. The protrusion 1318 is adapted to fit into the cavity 1302 of the die 1301. In the present embodiment, the protrusion 1318 and the cavity 1302 have complementary shapes.

In the step 1206, the die 1301 is aligned with the interposer layer 1314. This is illustrated in a schematic diagram 1320 of FIG. 13C where it is shown that alignment cameras 1322 are used to align the die 1301 with the interposer layer 1314 using the fiducials 1304, 1312.

In the step 1208, the die 1301 is placed on the interposer layer 1314 once the die 1301 is aligned with the interposer layer 1314 in the step 1206 to form a first planar contact 1332 between the protrusion 1318 and a first cavity wall of the cavity 1302. This is illustrated in the schematic diagram 1330 of FIG. 13D. As shown in FIG. 13D, the first planar contact 1332 of the present embodiment is in the x-y plane where the first cavity wall includes a portion of the front surface of the die 1301. In the present embodiment, the cavity 1302 is in the form of a depression, for example as previously shown in relation to FIG. 2B.

In the step 1210, an alignment check between the die 1301 and the interposer layer 1314 is performed. This is illustrated in a schematic diagram 1340 of FIG. 13E where it is shown that the alignment check between the laser diode 1301 and the interposer layer 1314 is performed using alignment cameras 1342.

If the alignment check between the die 1301 and the interposer layer 1314 as performed in the step 1210 is satisfactory, then the step 1212 is performed. In the step 1212, the die 1301 is displaced with respect to the interposer layer 1314 to form a second planar contact between the die 1301 and the interposer layer 1314. Laser-assisted bonding of the die 1301 to the interposer layer 1314 is also performed in this step 1212. This is illustrated in a schematic diagram 1350 of FIG. 13F where it is shown that heating 1352 is applied (e.g. using laser-assisted bonding) to the solder 1309 to form a bonding between the die 1301 and the interposer layer 1314. The heat-affected zone (HAZ) 1354 is also shown in FIG. 13F. The die 1301 is also displaced in a slide direction 1356, during the solder reflow/solder bonding, to form the second planar contact between the die 1301 and the interposer layer 1314. As shown in FIG. 13F, the second planar contact is in the x-z plane.

Alternatively, if the alignment check between the die 1301 and the interposer layer 1314 as performed in the step 1210 is not satisfactory, then the steps 1204 to 1210 are repeated. This is shown by the arrow 1214 in FIG. 12.

Once the die 1301 is bonded to the interposer layer 1314 in the step 1212, a post-bond alignment check is performed in the step 1216. This is illustrated in a schematic diagram 1360 as shown in FIG. 13G. Similar to earlier steps, alignment cameras 1362 are used to confirm that the die 1301 is aligned with the interposer layer 1314 after bonding. Also shown in FIG. 13G is the second planar contact 1364 formed between the protrusion 1318 and a second cavity wall of the cavity 1302.

In the above example, the alignment of the die with the interposer layer necessary means that the laser diode formed on the die is also aligned with the waveguide formed on the interposer layer, as the laser diode and the waveguide are formed on specific fixed positions on the die and the interposer layer respectively. It is therefore also clear that the fiducials formed on the die and/or the interposer layer can used for the alignment of the laser diode with the waveguide as described above.

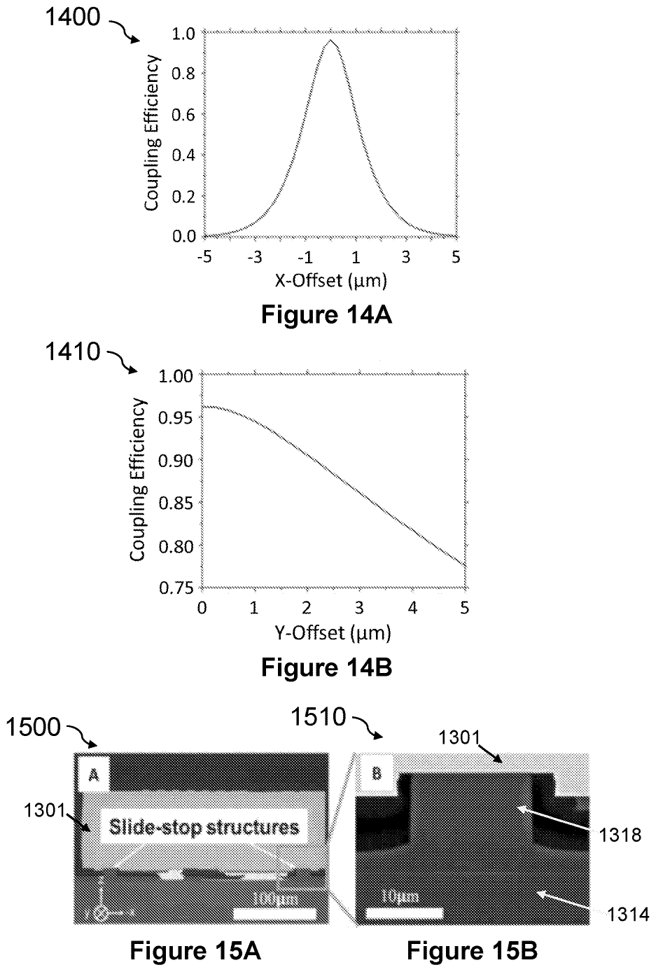

FIGS. 14A and 14B show plots of simulated laser-to-waveguide coupling efficiency with respect to deviations from an optical axis of the laser diode in accordance with an embodiment. FIG. 14A shows a plot 1400 of the simulated laser-to-waveguide coupling efficiency with respect to deviations from the optical axis along the x-axis, while FIG. 14B shows a plot 1410 of the simulated laser-to-waveguide coupling efficiency with respect to deviations from the optical axis along the y-axis in accordance with an embodiment.

As shown in FIGS. 14A and 14B, the X-axis offset of 1 μm causes more than 50% coupling loss between the laser diode and the waveguide, while the same amount of offset in the Y-axis causes less than 10% coupling loss. To reduce the coupling loss between the laser diode and the waveguide, the protrusion-cavity pair used for the alignment can therefore be customised to provide more confinement (or tighter control) with respect to the x-axis than the y-axis. In this way, the tighter fit along the x-axis can minimise unintentional lateral movement during the steps 1208 and 1212, where the die is being placed on the interposer layer and where heat was applied for the bonding of the die with the interposer layer, respectively. The tighter control along the x-axis ensures maximum launching of light from the laser diode into the waveguide, and significantly reduces coupling loss. In contrast, additional tolerance (or Y-offsets) between the protrusion and the cavity can be provided along the y-axis to enable easier or smoother placement of the die on the interposer layer. Further, the Y-offsets provide a space for displacing the die with respect to the interposer layer for making the second planar contact between the protrusion and a cavity wall of the cavity to improve alignment of the die and the interposer layer. Still further, heights of the protrusion and the cavity can also be designed to align the optical axis of the laser diode along the z-axis for efficient coupling of light launched from the laser diode into the waveguide.

The alignment of bonded laser optical axis to that of waveguide is important for coupling efficiency. Thus, bonded laser diodes have been ion-milled to verify their seating above the protrusion-cavity structure. FIGS. 15A and 15B show images illustrating the die-on-interposer alignment in accordance with an embodiment.

FIG. 15A shows an image 1500 of a cross-sectional view of a bonded die on the interposer layer, while FIG. 15B shows an image 1510 of a zoomed-in view of the protrusion-cavity pair. As shown in FIGS. 15A and 15B, the die 1301 is placed on the interposer layer 1314, where the protrusion-cavity pairs do not show any measurable gap. This forms the first planar contact between the protrusion 1318 and a first cavity wall (i.e. a portion of the front surface of the die 1301) of the cavity 1302.

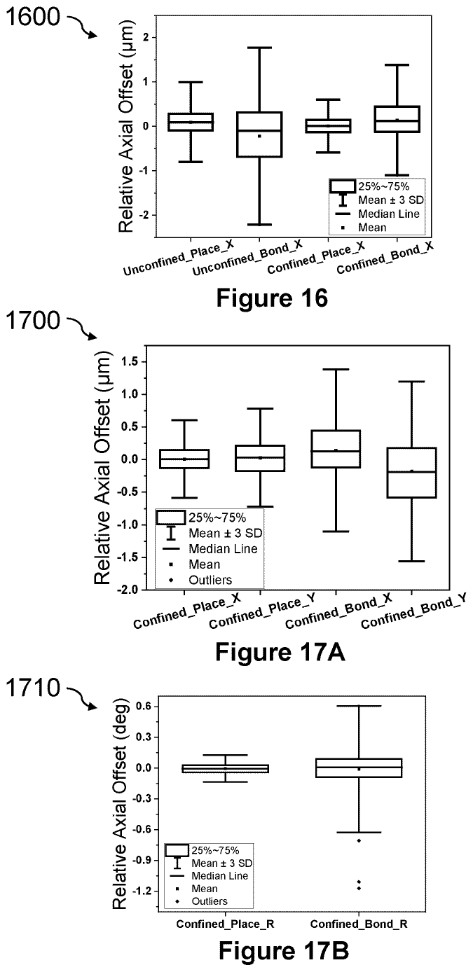

To demonstrate capability of the present alignment assembly and method, placement alignment accuracy and post-bond alignment accuracy of approximately 600 devices are illustrated using FIG. 16. FIG. 16 shows a plot 1600 of relative axial offsets in placement and bonding along the x-axis using the alignment method of FIG. 12 in accordance with embodiments.

As shown in the plot 1600 of FIG. 16, the placement alignment accuracy and the post-bond alignment accuracy of the laser diodes without incorporating a protrusion-cavity pair were measured to be 0.10 μm±0.90 μm @ 3-sigma and −0.22 μm±2.00 μm @ 3-sigma respectively. With the incorporation of the method of the present disclosure, the placement alignment accuracy and the post-bond alignment accuracy were improved to 0.01 μm±0.60 μm @ 3-sigma and 0.14 μm±1.24 μm @ 3-sigma respectively. The improvement in the placement alignment accuracy is calculated to be 85% in mean and 20% in 3-sigma spread. The improvement in the post-bond alignment accuracy is calculated to be 23% both in mean and in 3-sigma spread.

FIGS. 17A and 17B show plots of relative axial offsets before and after a laser-assisted bonding process in accordance with an embodiment. The assembly and the alignment method of the present disclosure were used for the results as shown in FIGS. 17A and 17B.

FIG. 17A shows a plot 1700 of relative axial offsets in the x-direction and the y-direction before and after the laser-assisted bonding process, and FIG. 17B shows a plot 1710 of relative axial offsets in the θ-direction before and after the laser-assisted bonding process. As shown in FIGS. 17A and 17B, the bonded laser diodes demonstrate a relative X-offset value of 0.14 μm±1.2 μm @ 3-sigma, a relative Y-offset value of −0.18 μm±1.38 μm @ 3-sigma, and a relative θ-offset value of −0.009°±0.616° @ 3-sigma.

A one-way ANOVA analysis was performed to verify the significance of using the alignment assembly (i.e. a protrusion-cavity pair) of the present disclosure for placement alignment and post-bond alignment accuracies. A p-value of less than 0.0001 was obtained and this shows that there is statistical significance between the placement alignment accuracy and the bonding alignment accuracy when the protrusion-cavity pair of the present disclosure is not used. On the other hand, a p-value of 0.08 was obtained between the placement alignment accuracy and the bonding alignment accuracy when the protrusion-cavity pair was used. This suggests that the placement alignment accuracy and the bonding alignment accuracy become statistically insignificant after the incorporation of using the alignment assembly and the method of FIG. 12 for the alignment process.

Table 1 shows coupling efficiency of laser diode (see FIG. 14A) against mean±3-sigma of the x-axis in relation to unconfined and confined alignment. Here, unconfined alignment relates to embodiments where the protrusion-cavity pair was not used, while confined alignment relates to embodiments where the protrusion-cavity pair was used.

TABLE 1
Coupling efficiency for unconfined and confined alignment

Coupling efficiency

| X-axis | Unconfined | Confined |
|---|---|---|
| Mean − 3-sigma | 0.20 | 0.58 |
| Mean | 0.96 | 0.98 |
| Mean + 3-sigma | 0.3 | 0.43 |

It is shown from Table 1 that the coupling efficiency spread is tightened for the confined alignment case as compared to the unconfined alignment case. Particularly, the coupling efficiency along the x-axis for the unconfined case reaches 0.2 at mean −3-sigma from a mean of 0.96, while the efficiency along the x-axis for the confined case reaches 0.43 at mean +3-sigma from a mean of 0.98.

To demonstrate the robustness of the alignment method of the present disclosure, directly-modulated laser (DML) diodes (having a diode size of 250 μm×150 μm) were bonded onto a transmit engine using the present alignment method.

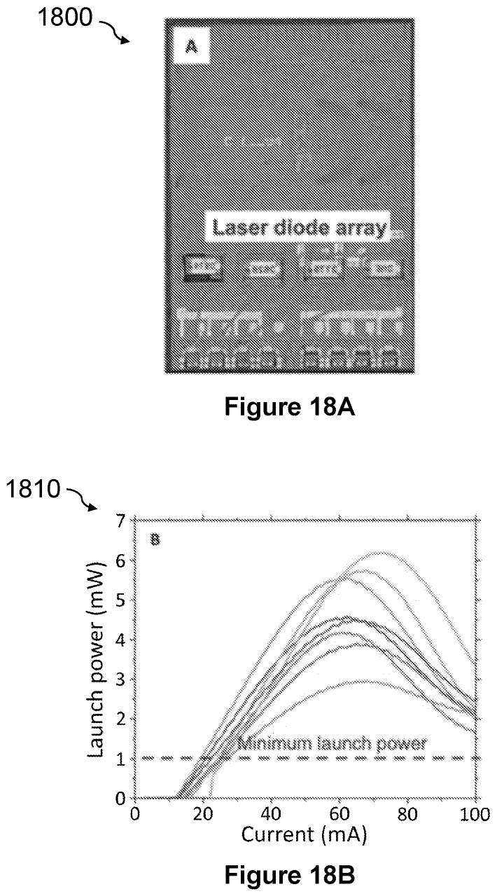

FIGS. 18A and 18B show an image 1800 of the bonded directly-modulated laser (DML) diode array and their performances, respectively.

As shown in the image 1800 of FIG. 18A, eight laser diodes are passively bonded onto a CMOS-based optical interposer. The optical outputs of these laser diodes are analysed with a probe system. During testing, the samples are seated on a copper block and held at 50° C.

As shown in the plot 1810 of FIG. 18B, the DMLs have average coupled power of 4 mW at 50 mA. The performance of these bonded DML diodes has exceeded the minimum launch power requirement of 1 mW. The measured optical outputs of these laser diodes, without thermal rollover despite their small form factor, suggests that a good bonding interface (electrical and thermal contact) and an effective alignment between the laser diodes and the interposer have been achieved.

Alternative embodiments of the invention include: (i) using other geometrical shapes, including irregular shapes, as cross-sections for the protrusion and/or the cavity; (ii) using protrusion and/or the cavity having variation in the x-y cross-section along the z-axis, for example, the protrusion can be in the form of a trapezoidal leg having a largest x-y cross-section at the base of the protrusion (i.e. the base is the plane that forms the planar contact with the cavity) and a narrower x-y cross section towards an opposite end of the base of the protrusion, and the cavity can be in a complementary shape to also confine the protrusion in the z-axis; (iii) using other semiconductor components or optical components other than the laser diode and waveguide as afore-described, this can include a light emitting diode, mirrors, a diffraction grating, a transistor etc.; (iv) the semiconductor components comprise optical components and/or electronic components; (v) the semiconductor components (e.g. a laser diode or a light emitting diode) having a more sensitive coupling efficiency in the y-direction than the x-direction; (vi) the protrusion formed on the second semiconductor component (e.g. the die) and the cavity formed on the first semiconductor component (e.g. the interposer layer), or vice versa; (vii) the cavity being in the form of a depression or a slot; (viii) the cavity being in the form of a C-shaped or a L-shaped or any other shape where at least two elastic averaging coupling or planar contacts can be made between the protrusion and the cavity walls; (ix) the protrusion-cavity pairs being formed at a middle of each edge of the semiconductor components (e.g. if the semiconductor components are of a square or a rectangular shape); (x) the first planar contact and the second planar contact being orthogonal to each other; (xi) the first planar contact and the second planar contact being at an angle with each other, where the angle ranges from 10° to 90°, from 10° to 80°, 20° to 70°, or 30° to 60°; (xii) the first planar contact being formed between the protrusion and a cavity wall of the cavity, for example where the cavity is formed by a cap or a depression; (xiii) displacing the first semiconductor component with respect to the second semiconductor component, while maintaining the first planar contact and the second planar contact, to provide a third planar contact between the protrusion and a cavity wall of the cavity; (xiv) performing a solder reflow process or a UV curing process for bonding of the first semiconductor component to the second semiconductor component; and (xv) the cavity and the protrusion not having complementary shapes (i.e. they have different cross-sectional shapes).

Although only certain embodiments of the present invention have been described in detail, many variations are possible in accordance with the appended claims. For example, features described in relation to one embodiment may be incorporated into one or more other embodiments and vice versa.

1. An assembly for sub-micron alignment of a first semiconductor component with a second semiconductor component, the assembly comprising:
a protrusion formed on a surface of the first semiconductor component; and
a cavity formed on a surface of the second semiconductor component and is adapted to receive the protrusion,
wherein in use, the first semiconductor component is placed in contact with the second semiconductor component via the protrusion to provide a first planar contact, and is subsequently displaced with respect to the second semiconductor component while maintaining the first planar contact to provide a second planar contact between the protrusion and a first cavity wall of the cavity for aligning the first semiconductor component with the second semiconductor component.

2. The assembly of claim 1, wherein a cross section of the protrusion and a cross-section of the cavity each has an acute internal angle.

3. The assembly of claim 1 or claim 2, wherein a cross-section of the protrusion and the cavity are defined by Cartesian coordinates in an X-Y plane, a minimum difference in lengths between the protrusion and the cavity in the X-direction and a minimum difference in lengths between the protrusion and the cavity in the Y-direction are equal to a placement accuracy at least of three Sigma of an alignment tool for aligning the first semiconductor component with the second semiconductor component.

4. The assembly of claim 3, wherein a maximum difference in lengths between the protrusion and the cavity in the X-direction and a maximum difference in lengths between the protrusion and the cavity in the Y-direction are defined by a minimal collision size associated with the protrusion and the cavity, wherein the minimal collision size is defined as the maximum differences in the X- and Y-dimensions of the protrusion to the cavity at which edges of the protrusion contact the cavity upon rotation of the protrusion within the cavity.

5. The assembly of claim 3 or claim 4, wherein a device performance associated with the first semiconductor component or the second semiconductor component is more sensitive in relation to the X-direction than the Y-direction, a difference in lengths in the X-direction between the protrusion and the cavity is less than a difference in lengths in the Y-direction between the protrusion and the cavity.

6. The assembly of any one of claims 3 to 5, wherein the second semiconductor component comprises a semiconductor die having an optical diode and the first semiconductor component comprises an interposer layer having a waveguide formed thereon, a height of the cavity or a height of the protrusion is adapted to align an optical axis of the optical diode in an X-Y plane of the semiconductor die with the waveguide for coupling light from the optical diode to the waveguide.

7. The assembly of any one of the preceding claims, wherein a volume of the protrusion is adapted to absorb mechanical energy resulted from contact impacts associated with the first and second planar contacts, and to plastically deform without fracturing.

8. The assembly of any one of the preceding claims, wherein the cavity is of a C-shaped or a L-shaped and is adapted to partially enclose the protrusion when in use.

9. The assembly of any one of the preceding claims, wherein the protrusion and the cavity form a protrusion-cavity pair, the assembly comprises two or more protrusion-cavity pairs.

10. The assembly of claim 9, wherein the two or more protrusion-cavity pairs are arranged at equidistant away from a thermal centre of the first semiconductor component or a thermal centre of the second semiconductor component, and are on diagonal lines passing through the thermal centre.

11. The assembly of claim 9 or claim 10, wherein the assembly includes four protrusion-cavity pairs, each of the four cavities are formed at each corner on the surface of the second semiconductor component or at each corner on the surface of the first semiconductor component.

12. The assembly of any one of claims 9 to 11, wherein a distance between each of the two or more protrusion-cavity pairs are adapted to be as large as possible within processing boundaries of the second semiconductor component.

13. The assembly of any one of the preceding claims, wherein the first planar contact and the second planar contact are orthogonal to each other.

14. The assembly of any one of the preceding claims, wherein the first planar contact is formed between the protrusion and a second cavity wall of the cavity.

15. The assembly of any one of the preceding claims, wherein in use, the first semiconductor component is displaced with respect to the second semiconductor component while maintaining the first planar contact and the second planar contact to provide a third planar contact between the protrusion and a third cavity wall of the cavity.

16. A method for sub-micron alignment of a first semiconductor component with a second semiconductor component using an assembly comprising a protrusion formed on a surface of the first semiconductor component and a cavity formed on a surface of the second semiconductor component adapted to receive the protrusion, the method comprising:
(i) aligning the first semiconductor component with the second semiconductor component to align the protrusion with respect to the cavity;
(ii) placing the first semiconductor component in contact with the second semiconductor component to provide a first planar contact via the protrusion; and
(iii) displacing the first semiconductor component with respect to the second semiconductor component while maintaining the first planar contact to provide a second planar contact between the protrusion and a first cavity wall of the cavity.

17. The method of claim 16, further comprising correlating a first fiducial on the surface of the first semiconductor component with a second fiducial on an opposite surface of the first semiconductor component.

18. The method of claim 16 or claim 17, wherein the first semiconductor component comprises an interposer layer and the second semiconductor component comprises a semiconductor die.

19. The method of any one of claims 16 to 18, wherein the protrusion and the cavity form a protrusion-cavity pair and the assembly comprises two or more protrusion-cavity pairs, aligning the first semiconductor component with the second semiconductor component comprises aligning the protrusion with respect to the cavity for each of the two or more protrusion-cavity pairs prior to the step (ii).

20. The method of any one of claims 16 to 19, wherein the first planar contact and the second planar contact are orthogonal to each other.

21. The method of any one of claims 16 to 20, further comprising forming the first planar contact between the protrusion and a second cavity wall of the cavity.

22. The method of any one of claims 16 to 21, further comprising displacing the first semiconductor component with respect to the second semiconductor component while maintaining the first planar contact and the second planar contact between the protrusion and the first cavity wall and the second cavity wall to provide a third planar contact between the protrusion and a third cavity wall of the cavity.
